(19) United States
(12) Patent Application Publication
(10) Pub. No.: US 2025/0056719 A1
(43) Pub. Date: Feb. 13, 2025

(54) CERAMIC SUBSTRATE, METHOD FOR MANUFACTURING CERAMIC SUBSTRATE, WIRING BOARD, PACKAGE, MICROPHONE DEVICE, AND GAS SENSOR DEVICE

(71) Applicant: KYOCERA Corporation, Kyoto-shi, Kyoto (JP)

(72) Inventor: Koutarou NAKAMOTO, Kyoto-shi (JP)

(73) Assignee: KYOCERA Corporation, Kyoto-shi, Kyoto (JP)

(21) Appl. No.: 18/721,448

(22) PCT Filed: Dec. 15, 2022
(86) PCT No.: PCT/JP2022/046163

§ 371 Date: Jun. 18, 2024

(30) Foreign Application Priority Data
Dec. 24, 2021 (JP) 2021-211249

(51) Int. Cl. H05K 1/03; H05K 1/02; H05K 1/18

(52) U.S. Cl. CPC H05K 1/0306; H05K 1/0298; H05K 1/181; H05K 2201/10083; H05K 2201/10151

(57) ABSTRACT

A ceramic substrate includes at least one first layer provided with a first through-hole and at least one second layer located overlapping the first layer. The second layer is provided with a plurality of second through-holes each having a smaller hole diameter than the first through-hole. The second through-holes include a plurality of inner through-holes located in an inside region of the first through-hole in plan view and a plurality of outer through-holes located in an outside region of the first through-hole in plan view.

### TECHNICAL FIELD

The present disclosure relates to a ceramic substrate, a method for manufacturing the ceramic substrate, a wiring board, a package, a microphone device, and a gas sensor device.

### BACKGROUND OF INVENTION

A substrate used to form a microphone device is provided with, for example, a sound opening. Patent Document 1 discloses a MEMS microphone in which a notch is formed in the lower part of a substrate and a plurality of fine holes are located in the notch as sound openings. Patent Document 2 discloses a microphone device including a lid in which a plurality of micropores are located in a notch.

Patent Document 3 discloses a ceramic member in which a thin ceramic plate in a window portion (large-diameter hole) is provided with a plurality of fine through-holes. Such a ceramic member may be used as a lid of a microphone device, a gas sensor device, or the like.

### CITATION LIST

### Patent Literature

Patent Document 1: U.S. Pat. No. 8,571,239

Patent Document 2: KR 10-1661923

Patent Document 3: JP 8-325053 A

### SUMMARY

A ceramic substrate according to an aspect of the present disclosure includes at least one first layer provided with a first through-hole; and at least one second layer located overlapping the first layer, in which the second layer is provided with a plurality of second through-holes each having a smaller hole diameter than the first through-hole, and the second through-holes include a plurality of inner through-holes located in an inside region of the first through-hole in plan view and a plurality of outer through-holes located in an outside region of the first through-hole in plan view.

A method for manufacturing a ceramic substrate according to an aspect of the present disclosure includes forming a first through-hole in a first sheet being a ceramic green sheet; forming a plurality of second through-holes each having a smaller hole diameter than the first through-hole in a region having an area larger than an opening area of the first through-hole in a second sheet being a ceramic green sheet; and layering the first sheet and the second sheet in a manner that some of the plurality of second through-holes are located on an outer side of the first through-hole in plan view.

A wiring board according to an aspect of the present disclosure includes the substrate and a wiring.

A method for manufacturing a wiring board according to an aspect of the present disclosure includes forming a first through-hole in a first sheet being a ceramic green sheet; forming a plurality of second through-holes each having a smaller hole diameter than the first through-hole in a region having an area larger than an opening area of the first through-hole in a second sheet being a ceramic green sheet; forming a wiring in the first sheet and/or the second sheet; and layering the first sheet and the second sheet in a manner that some of the plurality of second through-holes are located on an outer side of the first through-hole in plan view.

A package according to an aspect of the present disclosure includes the substrate as a lid, and a wiring board including an element mounting region at a position overlapping the first through-hole in plan view.

A microphone device according to an aspect of the present disclosure includes the wiring board or the package, and a microphone element.

A gas sensor device according to an aspect of the present disclosure includes the wiring board or the package, and a gas sensor element.

An electronic apparatus according to an aspect of the present disclosure includes the microphone device or the gas sensor device.

### BRIEF DESCRIPTION OF THE DRAWINGS

FIG. 1 is a cross-sectional view of a microphone device according to a first embodiment of the present disclosure.

FIG. 2 is a one point convergent view of an upper surface of an example of a wiring board according to the first embodiment of the present disclosure.

FIG. 3 is a one point convergent view of a lower surface of an example of the wiring board according to the first embodiment of the present disclosure.

FIG. 4 is a schematic plan view of an element mounting region of the wiring board according to the first embodiment of the present disclosure when viewed in plane perspective from the upper surface of the ceramic substrate.

FIG. 5 is a schematic plan view of an example of another array shape of the second through-holes.

FIG. 6 is a schematic plan view of another example of the shape of the first through-hole in an element mounting region of the ceramic substrate when viewed in plane perspective from the upper surface of the ceramic substrate 1.

FIG. 7 is a cross-sectional view of a variation of the ceramic substrate.

FIG. 8 is a cross-sectional view of a variation of the microphone device.

FIG. 9 is a cross-sectional view of a variation of the microphone device, and a mounting substrate.

FIG. 10 is a cross-sectional view of a variation of the microphone device, and a mounting substrate.

FIG. 11 is a cross-sectional view of a variation of the microphone device.

FIG. 12 is a cross-sectional view of a gas sensor device according to a second embodiment of the present disclosure.

FIG. 13 is a cross-sectional view of a variation of the gas sensor device.

FIG. 14 is a partial cross-sectional view of an electronic apparatus including the microphone device.

FIG. 15 is a partial cross-sectional view of an electronic apparatus including the microphone device.

FIG. 16 is a cross-sectional view of an electronic apparatus including the gas sensor device.

FIG. 17 is a cross-sectional view of an electronic apparatus including the gas sensor device.

### DESCRIPTION OF EMBODIMENTS

For a substrate on which an element such as a microphone element is mounted, a bonding material or the like for mounting the element is applied to the outside of a region in which the fine through-holes are provided. The bonding material or a metal material may block the fine through-holes conducting from the outside of the substrate to the element.

For example, a microphone module in which a microphone is mounted on a mounting substrate is mounted on an electronic apparatus such as a smartphone. When a substrate having fine through-holes is used as a lid, a sealing material is disposed around a region where the fine through-holes of the substrate are provided between a casing of the electronic apparatus and the substrate. In this case, the sealing material may block the fine through-holes.

Any of the above-described substrates can be obtained by a ceramic substrate manufactured by layering a layer having a large diameter hole and a layer having fine holes, but the fine through-holes may be blocked also by positional misalignment in the layering step.

Thus, known substrates could have a decreased number of through-holes that conduct from the outside of the substrate to the element due to spreading of the bonding material or the sealing material or due to layering misalignment in the manufacturing process of the substrate.

In the ceramic substrate of the present disclosure, the likelihood of a decrease in the number of through-holes that conduct from the outside of the substrate to the element due to spreading of the bonding material or the sealing material or due to layering misalignment in the manufacturing process of the substrate, can be reduced.

### First Embodiment

### Configuration of Microphone Device 200

An embodiment of the present disclosure will be described in detail below with reference to accompanying drawings. The description “parallel” only means being parallel at a visible level and does not need to be strictly parallel. The description “perpendicular” only means being perpendicular at a visible level and does not need to be strictly perpendicular.

In a first embodiment, an example in which a ceramic substrate or a wiring board according to the present disclosure is applied to a microphone device will be described.

The distinction between top and bottom in the following description is for convenience only and does not limit the actual top and bottom of the package and microphone device when it is used. In this specification, a surface on a side on which the microphone element 3 is mounted in a ceramic substrate 1 or a wiring board 10 is defined as an upper surface. In the drawings, the positive Z-axis direction is the upward direction. The X-axis direction is the major axis direction of the ceramic substrate 1 or the wiring board 10, and the Y-axis is the axis that intersects the X-axis and Z-axis perpendicularly.

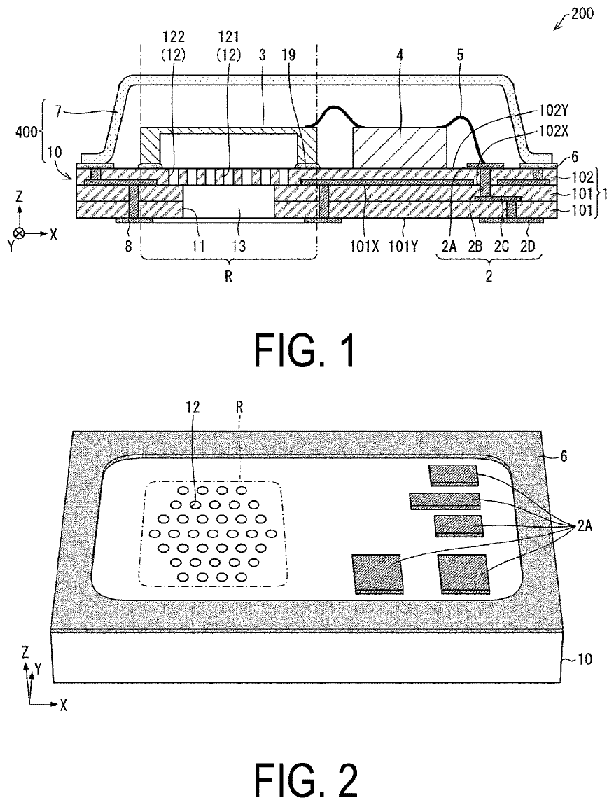

FIG. 1 is a cross-sectional view of a microphone device 200 when cut along a plane perpendicular to the upper surface of the wiring board 10 and parallel to the X-axis direction. FIG. 1 illustrates the ceramic substrate 1, the wiring board 10 including the ceramic substrate 1 and wiring 2, and the microphone device 200 including the wiring board 10, a microphone element 3, and a semiconductor element 4 according to the present disclosure. A micro electro mechanical systems (MEMS) microphone device in which the microphone element 3 is a MEMS microphone is illustrated.

The microphone device 200 illustrated in FIG. 1 is an example with a lid 7. A configuration including the wiring board 10 and the lid 7 is referred to as a package 400. That is, the microphone device 200 may include the package 400 and the microphone element 3. The microphone device 200 includes the lid 7, but the microphone device 200 need not include the lid 7.

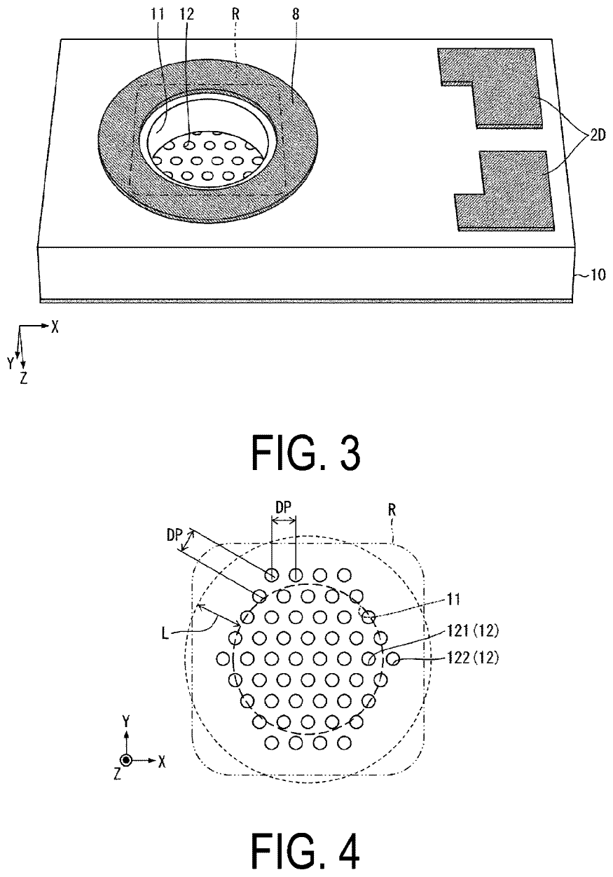

FIG. 2 is a one point convergent view illustrating an upper surface of an example of the wiring board 10. FIG. 3 is a one point convergent view illustrating a lower surface of the example of the wiring board 10.

Constituent elements of the microphone device 200 will be described in detail below.

### Ceramic Substrate 1

As illustrated in FIG. 1, the ceramic substrate 1 includes a first layer 101 having a first through-hole 11. The ceramic substrate 1 also includes a second layer 102 which is located overlapping the first layer 101 and has second through-holes 12 each having a hole diameter smaller than that of the first through-hole 11. The ceramic substrate 1 has, for example, a quadrangle shape such as a rectangular shape or a square shape in plan view. The first layer 101 and the second layer 102 are insulation layers each made of an insulation material including, for example, a ceramic material such as an aluminum oxide-based sintered body, a glass ceramic sintered body, a mullite-based sintered body, or an aluminum nitride-based sintered body.

The first layer 101 has a third surface 101X facing the second layer 102 and a fourth surface 101Y located on the opposite side of the third surface 101X. The fourth surface 101Y of the lowermost first layer 101 constitutes a part of the outer surface (lower surface) of the ceramic substrate 1. The thickness of the first layer 101 is, for example, 0.02 mm or more and 0.20 mm or less. On the fourth surface 101Y, the first through-hole 11 is circular, for example, and its diameter is 0.1 mm or more and 1.0 mm or less, for example.

The second layer 102 has a second surface 102X on the side facing the first layer 101 and a first surface 102Y located on the opposite side of the second surface 102X. The first surface 102Y of the uppermost second layer 102 constitutes a part of the outer surface (upper surface) of the ceramic substrate 1. In other words, the ceramic substrate 1 has the first surface 102Y and the fourth surface 101Y, which are part of the outer surfaces.

The ceramic substrate 1 has a plurality of the second through-holes 12 each being smaller and finer than the first through-hole 11, so that the ceramic substrate 1 can be a substrate that allows gas to pass therethrough but does not allow water to pass therethrough. The thickness of the second layer 102 is, for example, 0.02 mm or more and 0.20 mm or less. The second through-holes 12 are substantially circular, and each have a diameter of, for example, 0.010 mm or more and 0.050 mm or less. With the thickness of the second layer 102 and the diameter of each of the second through-holes 12 in the above ranges, the ceramic substrate 1 can have excellent waterproof performance. The thickness of the second layer 102 of 0.20 mm or less enables excellent ventilation. This allows for excellent acoustic characteristics when the ceramic substrate 1 is applied to a microphone device.

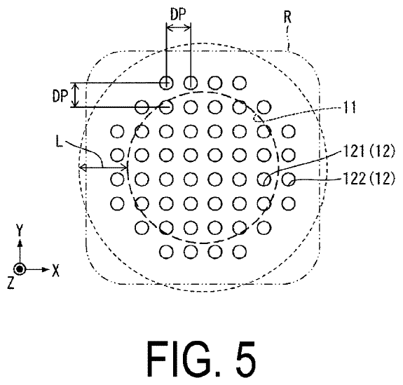

The second through-holes 12 are arranged at a constant array pitch (hole pitch) in the second layer 102. The hole pitch of the second through-holes 12 can be set appropriately according to the thickness of the second layer 102, the size of the second through-holes 12, and the size of the first through-hole 11, in consideration of the characteristics, strength, and the like required for the microphone device or gas sensor device using the ceramic substrate 1. The hole pitch of the second through-holes 12 is, for example, 0.05 mm or more and 0.30 mm or less. The hole pitch referred to here is a distance between the centers of the second through-holes 12 as indicated by DP in FIGS. 4 and 5. The second through-holes 12 in FIG. 5 are arranged in a lattice array (square lattice array), in which the center-to-center distance in the X-direction and the Y-direction, that is, the shortest center-to-center distance is set as the hole pitch DP. Since the array of the second through-holes 12 in FIG. 4 is a 60-degree staggered array (also referred to as a regular triangular lattice array), the hole pitch DP is the same in any direction.

As illustrated in FIGS. 1 and 2, the first surface 102Y of the second layer 102 includes an element mounting region R. The element mounting region R is illustrated also in FIG. 3, but the element mounting region R in FIG. 3 is obtained by projecting the element mounting region R of the first surface 102Y onto the fourth surface 101Y (lower surface) in order to understand the positional relationship between the first through-hole 11 and the element mounting region R. In the present embodiment, the element mounting region R is a region in which the microphone element 3 is mounted. The element mounting region R may be a region overlapping the microphone element 3 mounted on the element mounting region R of the first surface 102Y. Alternatively, the element mounting region R may be the region surrounded by virtual lines connecting alignment marks that are located on the first surface 102Y and used in mounting the microphone element 3 on the element mounting region R.

FIG. 4 is a schematic plan view of the element mounting region R of the wiring board 10 when viewed in plane perspective from the upper surface of the wiring board 10 (in the Z-axis positive direction). As illustrated in FIG. 4, since the element mounting region R is located surrounding the first through-hole 11 in plane perspective, the acoustic characteristics of the microphone device 200 can be improved.

When the ceramic substrate 1 is viewed in plane perspective, the second through-holes 12 include a plurality of inner through-holes 121 located in an inside region of the first through-hole 11 and a plurality of outer through-holes 122 located in an outside region of the first through-hole 11. The inside region of the first through-hole 11 means a region on an inner side of the outer edge of the first through-hole 11 when the ceramic substrate 1 is viewed in plane perspective. The outside region of the first through-hole 11 means a region on an outer side of the outer edge of the first through-hole 11 when the ceramic substrate 1 is viewed in plane perspective. The second through-holes 12 are located at the same hole pitch from the inside region to the outside region of the first through-hole 11. The second through-hole 12 located across the inside region and the outside region of the first through-hole 11 is defined as the inner through-hole 121.

The ceramic substrate 1 has the second through-holes 12 located from the inside region to the outside region of the first through-hole 11. In other words, the first through-hole 11 is located within the arrangement region of the second through-holes 12. Therefore, in the ceramic substrate 1, the second through-holes 12 are not blocked by the first layer 101 in the first through-hole 11, even when the center of the arrangement region of the second through-holes 12 and the center of the first through-hole 11 do not coincide with each other.

As illustrated in FIG. 1, when the microphone device 200 is formed using the ceramic substrate 1, the microphone element 3 is bonded to the ceramic substrate 1 with a bonding material 19. In this case, the inner through-holes 121 are effective through-holes that conduct electricity from the outside of the substrate to the element and effectively act as sound openings that take in sound from the outside. In the case in which the ceramic substrate 1 has the outer through-holes 122, even when the bonding material 19 spreads during the bonding step of bonding the microphone element 3, the spreading of the bonding material 19 toward the first through-hole 11 (toward the inner through-holes 121) is suppressed by the outer through-holes 122. This reduces the likelihood of blocking of the inner through-holes 121 with the bonding material 19. In other words, the likelihood of a decrease in the number of effective through-holes due to the spreading of the bonding material 19 can be reduced, and the likelihood of deterioration of the acoustic effects of the microphone device 200 can be reduced. The strength of the bonding is improved by the anchoring effect when the bonding material 19 slightly enters the outer through-holes 122.

The outer through-holes 122 may be located in the outside region of the first through-hole 11 and inside the element mounting region R. This reduces the likelihood of spreading of the bonding material 19 toward the first through-hole 11 side.

The outer through-holes 122 may be located at positions overlapping the element bonding region (region where the bonding material is placed) of the element mounting region R. Since the bonding material 19 also spreads outward from the element mounting region R, a part of the element bonding region may be located outside the element mounting region R. The outer through-holes 122 positioned overlapping the element bonding region allow the bonding material 19 to slightly enter the outer through-holes 122, thus improving the bonding strength.

The above-described effect cannot be obtained when the outer through-holes 122 are located outside the element mounting region R or the bonding region. The second through-holes 12 are fine through-holes, so that the cost for manufacturing the ceramic substrate 1 increases with an increase in the number of the second through-holes 12. By limiting the region where the outer through-holes 122 are present, both the effect of reducing the likelihood of blocking the effective through-holes with the bonding material 19 or the like and the effect of suppressing an excessive increase in the manufacturing cost of the ceramic substrate 1 can be achieved. The likelihood that the number of the second through-holes 12 becomes excessive and the strength of the ceramic substrate 1 is reduced can be reduced.

Therefore, as illustrated in FIG. 4, the outer through-holes 122 may be located in a region which is a region outside the first through-hole 11 in plane perspective and defined by a distance L(L=2DP) outward from the outer edge of the first through-hole 11 by two hole pitches DP of the second through-holes 12.

The array shape of the plurality of second through-holes 12 in the second layer 102 is not particularly limited, but as illustrated in FIG. 4, the second through-holes 12 may be in a staggered array in the second layer 102. More specifically, the second through-holes 12 may be in a 60-degree staggered array. FIG. 5 is a schematic plan view of another example of the array shape of the second through-holes 12, illustrating the element mounting region R of the ceramic substrate 1 when viewed in plane perspective from the upper surface of the ceramic substrate 1 (in the Z-axis positive direction). In FIG. 5, the second through-holes 12 are in a lattice array.

In FIGS. 4 and 5, the distance between the second through-holes 12 (hole pitch DP) is the same in the staggered array and the lattice array. The diameters of the second through-holes 12 are the same. When the staggered array is compared with the lattice array, the number of the inner through-holes 121 is larger in the staggered array because the interval in the Y-axis direction is smaller in the staggered array. That is, in the staggered array, more second through-holes 12 of the same diameter can be placed per unit area than in the lattice array with the same hole pitch DP. Among the staggered arrays, in the 60-degree staggered array in which an equilateral triangle is formed when the centers of adjacent holes are connected by a straight line, the largest number of the second through-holes 12 can be placed per unit area.

To achieve good acoustic characteristics in the microphone device 200, the ratio of the sum of the areas of the hole portions of the inner through-holes 121, which are effective through-holes, to the area of the hole portion of the first through-hole 11 is preferably higher. That is, the greater the number of the inner through-holes 121, the better. In light of the above, the second through-holes 12 may be in the staggered array for acoustic characteristics. The acoustic characteristics of the microphone device 200 can be improved by arranging the plurality of second through-holes 12 in the staggered array.

The hole pitch DP of the second through-holes 12 is the same in the lattice array and the 60-degree staggered array, and the strength of the ceramic substrate 1 is unlikely to be reduced even when the number of the second through-holes 12 is increased by employing the 60-degree staggered array. When compared with other staggered arrays, the 60-degree staggered array has higher strength because the distance between holes is the same for all holes and no areas are provided in which the distance between holes is small and the strength is low, which less likely causes the starting point for fracture. Thus, the strength and acoustic characteristics of the microphone device 200 can be improved when the second through-holes 12 are in the 60-degree staggered array.

The ceramic substrate 1 is a layered structure of ceramic insulation layers, allowing formation of a three-dimensional wiring structure. Since layers of different thicknesses can be layered, the fine second through-holes 12 can be formed in a thin second layer 102, which is easy to form, and layered with the first layer 101 or multiple first layers having sufficient thickness to ensure strength of the entire substrate. The ceramic substrate 1 can also reduce corrosion and degradation by water or gases compared with substrates made of a metal or organic materials. The ceramic substrate 1 can have a higher strength than a substrate made of silicon. As a result, the ceramic substrate 1 can be made thinner. The high strength allows an increased number of through-holes and an increased total area of opening portions of the effective through-holes.

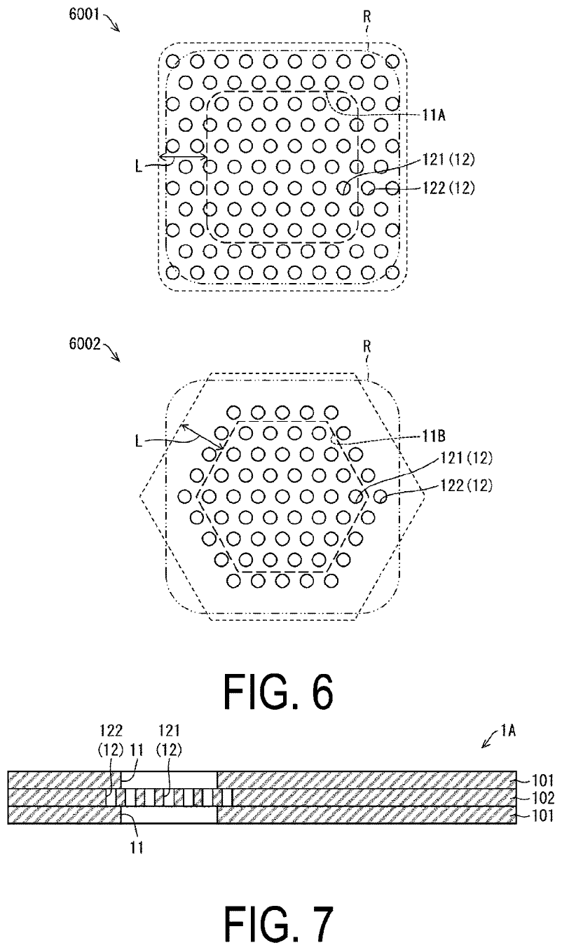

FIG. 6 is a schematic plan view of another example of the shape of the first through-hole 11, illustrating the element mounting region R of the ceramic substrate 1 when viewed in plane perspective from the upper surface of the ceramic substrate 1 (in the Z-axis positive direction).

The cross-sectional shape of the first through-hole 11 in a plane parallel to the ceramic substrate 1 (X-Y plane) is not limited to a circular shape, but may be a polygonal shape such as a quadrangle.

For example, the figure indicated by a reference sign 6001 in FIG. 6 illustrates an example in which the first layer 101 has a first through-hole 11A having a quadrangle cross-sectional shape. For example, in the dimensions of the first through-hole 11, the length of a side of the quadrangle (distance between opposing sides) corresponds to the diameter described above. When the first through-hole 11 has a polygonal shape, each corner portion may have a rounded shape as with the first through-hole 11A. As with the first through-hole 11A, the quadrangle cross-sectional shape can increase the number of effective through-holes. When the cavity shape of the microphone element 3 is a quadrangle in plan view, the quadrangle-shaped first through-hole 11 may be employed.

The figure indicated by a reference sign 6002 in FIG. 6 illustrates an example in which the first layer 101 has a first through-hole 11B having a hexagonal cross-sectional shape. When the cross-sectional shape of the first through-hole 11 is a regular hexagonal shape as with the first through-hole 11B, the array shape of the second through-holes 12 may be the 60-degree staggered array. This configuration can increase the number of effective through-holes.

FIG. 1 illustrates an example of the ceramic substrate 1 having a three-layer structure in which two first layers 101 and one second layer 102 are layered, but the ceramic substrate 1 needs only to include at least one first layer 101 and at least one second layer 102.

FIG. 7 is a cross-sectional view of a ceramic substrate 1A as a variation of the ceramic substrate 1. As with the ceramic substrate 1A illustrated in FIG. 7, the second layer 102 may be sandwiched between two first layers 101. That is, the opening of the first through-hole 11 is on each side of the ceramic substrate 1A with the second through-hole 12 therebetween. This configuration can reduce the likelihood of damage to the second through-holes 12 due to contact with external objects. This configuration also reduces the likelihood of a decrease in the number of through-holes conducting from the outside of the substrate to the element due to layering misalignment in the manufacturing process of the substrate.

### Method for Manufacturing Ceramic Substrate 1

The ceramic substrate 1 can be manufactured by, for example, the following manufacturing method including the following first to fifth steps. Either the second step or the third step may be performed first, or the second step and the third step may be performed in parallel.

The first step is to prepare a first sheet which is a ceramic green sheet to be the first layer 101 by firing and a second sheet which is a ceramic green sheet to be the second layer 102 by firing. In the first step, raw material powder of aluminum oxide, silicon oxide, or the like is formed into a sheet shape together with an appropriate organic binder and an appropriate organic solvent to produce the first sheet and the second sheet.

The second step is to form the first through-hole 11 in the first sheet. The first through-hole 11 is formed by punching the first sheet using a metal mold or the like. The hole diameter at the time of punching is such that the hole diameter after firing is 0.1 mm or more and 1.0 mm or less.

The third step is to form a plurality of second through-holes 12 in the second sheet. More specifically, in the third step, a plurality of the second through-holes 12 each having a hole diameter smaller than that of the first through-hole 11 are formed in a region of the second sheet having an area larger than the opening area of the first through-hole 11. At this time, the position of the region in which the plurality of second through-holes 12 are formed overlaps the first through-hole 11 when the first sheet and the second sheet are layered in the subsequent fourth step. That is, the region in which the plurality of second through-holes 12 are formed is the region including the first through-hole 11 and being larger than the opening portion of the first through-hole 11 in plane perspective when the first sheet and the second sheet are layered in the subsequent fourth step. For example, the region where the second through-holes 12 are formed may be the region defined by a distance L(L=2DP) outward from the outer edge of the first through-hole 11 by two hole pitches DP in plane perspective at the time of the layering. This configuration can reduce the likelihood of a decrease in the number of the inner through-holes 121 even when the layering misalignment of about two hole pitches DP occurs during layering. Specifically, when the hole pitch is 0.30 mm, a layering misalignment of about 0.60 mm can be tolerated.

The second through-holes 12 are formed, for example, by punching the second sheet using a metal mold or the like. A hole diameter at the time of punching is such a size that the hole diameter after firing is 0.010 mm or more and 0.050 mm or less. The first through-hole 11 and the second through-holes 12 may be formed using a laser.

The fourth step is to layer the first sheet and the second sheet such that some of the plurality of second through-holes 12 are located on an outer side of the first through-hole 11 in plan view.

The fifth step is to fire the layered body obtained by the layering in the fourth step at a temperature of 1300° C. or more and 1600° C. or less.

Since the ceramic green sheet shrinks upon firing by approximately 10% to 20%, the holes formed in the green sheet can each have a hole diameter larger than the diameters of the first through-hole 11 and the second through-holes 12 after firing by approximately 10% to 20%. Since the ceramic green sheet before firing is a soft material, fine hole processing as described above is easy. Therefore, it is easy to form fine through-holes, in the ceramic substrate 1, such as those having a diameter of 100 um or less, which is considered difficult to form with a metal substrate or an organic substrate. The method of forming fine through-holes in the ceramic green sheet using a metal mold or the like has higher productivity than a method of forming through-holes in a substrate made of silicon or the like by etching. That is, the ceramic substrate 1 can improve productivity compared with substrates made of other materials.

The thinner the ceramic green sheet is, the easier it is to form fine through-holes. By using a thin green sheet as the ceramic green sheet constituting the second layer 102, the fine second through-holes 12 can be easily formed. The ceramic green sheet forming the first layer 101 can have a thickness and the number of layers corresponding to the strength required for the ceramic substrate 1. That is, in the fourth step, a plurality of the first layers 101 may be layered. The ceramic substrate 1 is a layered body consisting of the second layer 102 with the fine second through-holes 12 and other first layers 101, making it easier to have the fine through-holes and ensuring the required substrate thickness.

The method for manufacturing the ceramic substrate according to the present disclosure includes a step of forming the first through-hole 11 in the first sheet that is the ceramic green sheet. The method for manufacturing the ceramic substrate according to the present disclosure includes a step of forming the plurality of second through-holes 12 each having a diameter smaller than that of the first through-hole 11 in the region having an area larger than the opening area of the first through-hole 11 in the second sheet, which is the ceramic green sheet. The method for manufacturing the ceramic substrate according to the present disclosure includes a step of layering the first sheet and the second sheet such that some of the plurality of second through-holes 12 are located on an outer side of the first through-hole 11 in plan view.

This manufacturing method provides the ceramic substrate 1 including the plurality of inner through-holes 121 located in the inside region of the first through-hole 11 and the plurality of outer through-holes 122 located in the outside region of the first through-hole 11 in plane perspective. That is, the substrate in which the likelihood of blocking the effective through-holes by the bonding material or the sealing material can be reduced can be produced.

After the third step, the second sheet includes the plurality of second through-holes 12 each having a hole diameter smaller than that of the first through-hole 11 in the region having an area larger than the opening area of the first through-hole 11. Therefore, even when the positional misalignment occurs in the laminate of the first sheet and the second sheet in the fourth step, the likelihood of a decrease in the number of effective through-holes can be reduced.

### Wiring Board 10

As illustrated in FIG. 1, the wiring board 10 includes the ceramic substrate 1 and the wiring 2.

For example, in the example illustrated in FIG. 1, the wiring board 10 includes, as the wiring 2, a connection pad 2A, a terminal electrode 2D, a through-hole conductor 2B, and an internal wiring layer 2C. On the upper surface of the wiring board 10, the connection pad 2A for connection to the microphone element 3 and a bonding metal layer 6 are provided. The terminal electrode 2D for connection to an external electrical circuit is provided on the lower surface of the wiring board 10. The connection pad 2A and the terminal electrode 2D are electrically connected to each other by the through-hole conductor 2B and the internal wiring layer 2C provided inside the wiring board 10. The through-hole conductor 2B penetrates through the insulation layers (the first layer 101 and the second layer 102), and the internal wiring layer 2C is located between the insulation layers. The terminal electrode 2D may be provided from the lower surface to the side surface, or on the side surface, instead of on the lower surface of the wiring board 10. A sealing metal layer 8 surrounding the opening of the first through-hole 11 is provided on the lower surface of the wiring board 10.

The wiring 2, the bonding metal layer 6, and the sealing metal layer 8 mainly contain, for example, a metal such as tungsten, molybdenum, manganese, copper, silver, palladium, gold, platinum, nickel, or cobalt, or an alloy containing any of these metals, as a conductor material. The wiring 2, the bonding metal layer 6, and the sealing metal layer 8 are formed on the surface of the wiring board 10 as metallized or plated layers of the conductor materials. The metal layer may be a single layer, or a plurality of layers. The wiring 2 is formed inside the wiring board 10 by metallization of the conductor material.

A method for manufacturing the wiring board according to the present disclosure may additionally include a step of forming the wiring 2 in the first sheet and/or the second sheet before the fourth step in the method for manufacturing the ceramic substrate described above. The other steps are the same as those of the method for manufacturing the ceramic substrate.

The connection pad 2A, the internal wiring layer 2C, and the terminal electrode 2D of the wiring 2, the bonding metal layer 6, and the sealing metal layer 8 can be formed as follows. For example, when the wiring 2 is a metallized layer of tungsten, it can be formed by printing a metal paste made by mixing tungsten powder with an organic solvent and organic binder at predetermined positions on the first sheet and the second sheet by a screen printing method or the like. The through-hole conductor 2B may be formed by creating a through-hole at a predetermined position in the ceramic green sheet prior to printing of the metal paste described above and filling this through-hole with a metal paste the same as or similar to the metal paste described above.

An exposed surface of the metallized layer after firing may be further coated with a plating layer of nickel, gold, or the like using an electrolytic plating method or an electroless plating method.

That is, the method for manufacturing the wiring board according to the present disclosure includes the following steps. A step of forming the first through-hole 11 in the first sheet that is a ceramic green sheet. A step of forming the plurality of second through-holes 12 each having a hole diameter smaller than that of the first through-hole 11 in a region having a larger area than the opening area of the first through-hole 11 in the second sheet that is the ceramic green sheet. A step of forming the wiring on the first sheet and/or the second sheet. A step of layering the first sheet and the second sheet in a manner that some of the plurality of second through-holes 12 are located on an outer side of the first through-hole 11 in plan view.

This manufacturing method can manufacture the wiring board in which the likelihood of blocking the effective through-holes with the bonding material or the sealing material can be reduced. Even when the positional misalignment occurs in the laminate of the first sheet and the second sheet, the likelihood of a decrease in the number of the effective through-holes can be reduced.

The wiring board 10 includes the ceramic substrate 1 and the wiring 2. As with the ceramic substrate 1, the wiring board 10 is the substrate in which the second through-holes 12 are not blocked by the first layer 101 in the first through-hole 11 even when the center of the region in which the second through-holes 12 are located does not coincide with the center of the first through-hole 11. This also reduces the likelihood of a decrease in the number of through-holes conducting from the outside of the substrate to the element due to layering misalignment in the manufacturing process of the wiring board 10. In the bonding step of bonding the microphone element 3, the wiring board 10 in which the likelihood of a decrease in the number of the effective through-holes can be reduced can be obtained even when the bonding material 19 spreads.

### Microphone Element 3

The microphone element 3 is a MEMS microphone semiconductor element with a diaphragm or beam structure, such as a sensor device with a vibrating electrode, and is fixed to the element mounting region R on the wiring board 10. The microphone element 3 is fixed, for example, by bonding the lower surface of the microphone element 3 to the element mounting region R of the wiring board 10 with the bonding material 19. An electrode (not illustrated) disposed on the upper surface of the microphone element 3, and the wiring board 10 or the semiconductor element 4 are electrically connected to each other by a connecting member 5.

In the microphone device 200, the terminal electrode 2D provided on the lower surface of the wiring board 10 of the wiring 2 and the external electrical circuit are electrically connected to each other, and thus the microphone element 3 mounted on the wiring board 10 and the external electrical circuit are electrically connected to each other. That is, the microphone element 3 and the external electrical circuit are electrically connected via the connecting member 5 such as a bonding wire and the wiring 2. The external electrical circuit is, for example, an electrical circuit included in a mounting substrate (circuit board) mounted in an electronic apparatus such as a smartphone.

The microphone element 3 includes, for example, a diaphragm and a back plate. The diaphragm and the back plate act like a parallel flat plate type capacitor, and when the diaphragm vibrates due to sound pressure, a gap length between the diaphragm and the back plate changes and electrostatic capacitance changes. The microphone element 3 transmits this change as an electrical signal to the semiconductor element 4.

The semiconductor element 4 is, for example, an integrated circuit such as an Application Specific Integrated Circuit (ASIC) and the like. The semiconductor element 4 has, for example, a function of amplifying the electrical signal received from the microphone element 3. The semiconductor element 4 is, for example, electrically connected to the microphone element 3 and the wiring board 10 by the connecting member 5. In addition to the semiconductor element 4, a passive component (not illustrated) such as a capacitor may be mounted on the wiring board 10. The passive component is, for example, connected to the connection pad 2A by soldering.

### Lid

In the example illustrated in FIG. 1, the microphone element 3 is sealed and protected by the lid 7 on the upper surface side of the wiring board 10. In the example illustrated in FIG. 1, the microphone device 200 includes the lid 7 having a box shape (cap shape) collectively covering the connection pad 2A, the microphone element 3, and the connecting member 5, which are on the upper surface of the wiring board 10.

The lid 7 is made of a material such as a metal, a resin, and a ceramic, and is bonded to the wiring board 10. The lid 7 may be bonded via a sealing bonding material. Examples of the sealing bonding material include, for example a resin adhesive, glass, and a brazing material including solder. When the lid 7 and the wiring board 10 are bonded to each other using the brazing material, the bonding metal layer 6 may be provided on the upper surface of the wiring board 10 so as to surround the region R and the connection pad 2A disposed outside the region R on the upper surface of the wiring board 10. The lid 7 may be bonded to the bonding metal layer 6 on the wiring board 10 by seam welding, laser welding, or other welding when the lid 7 is metal. In the case of bonding using the brazing material or the like, an overall heating by reflow heating is performed, whereas in the case of bonding by seam welding or laser welding, local heating of only the bonding portion can be performed. Thus, influence of heat on the microphone element 3 and the semiconductor element 4 can be reduced. The bonding metal layer 6 may be formed of, for example a metal film such as a plating film, a metallized layer, or the like. In a case where the lid 7 is formed of a material having low wettability (bonding property) of the brazing material such as a resin or a ceramic, the bonding metal layer may be formed also on the lid 7.

In a case where the lid 7 is made of an electrically conductive material such as a metal, the lid 7 can function as a shield member against noise entering from outside. As illustrated in FIG. 1, the bonding metal layer 6 and the sealing metal layer 8 may be connected to each other by the wiring 2 (the through-hole conductor 2B and the internal wiring layer 2C). Since the sealing metal layer 8 is connected to the ground potential of the external circuit, the lid 7 is connected to the ground potential of the external circuit via the wiring 2 and the sealing metal layer 8. This configuration allows for a better shielding property by connection to the ground potential through the bonding metal layer 6. Thus, acoustic noise is reduced, and the reliability of operation is improved.

### Conclusion

The microphone device 200 includes the wiring board 10 and the microphone element 3. This configuration allows excellent waterproof characteristics. The microphone device 200 in which the likelihood of deterioration of the acoustic effects of the microphone device 200 caused by a decreased number of effective through-holes can be reduced, due to spreading of the bonding material 19, can be implemented.

In the microphone device 200, the second layer 102 of the wiring board 10 has the second surface 102X facing the first layer 101 and the first surface 102Y located on the opposite side of the second surface. The first surface 102Y includes the element mounting region R, and the element mounting region R is located surrounding the first through-hole 11 in plan view.

This configuration allows implementation of the wiring board in which the likelihood of a decrease in the number of effective through-holes can be reduced even when the bonding material 19 spreads in the bonding step of bonding the microphone element 3. The second layer 102 reduces the likelihood of water entering through the opening portions in the mounting substrate and reaching the microphone element 3. Even when water enters through the first through-hole 11, the presence of the outer through-holes 122 hinders water from reaching the microphone element 3.

Since the microphone element 3 is mounted on the first surface 102Y when the wiring board 10 is used as the substrate for mounting the microphone element 3, the acoustic characteristics can be improved. A recessed portion 13 defined by the first through-hole 11 of the first layer 101 and the lower surface of the second layer 102 is formed in the lower surface of the wiring board 10, so that the likelihood of damage to the second layer 102 due to contact with external objects can be reduced. The recessed portion 13 acts as an air reservoir, reducing the likelihood of water from outside reaching the second layer 102. Since no recessed portion 13 is formed on the upper surface of the wiring board 10, the element mounting region R is easily flattened, reducing the likelihood of tilting when mounting the microphone element 3.

### First Variation of Microphone Device

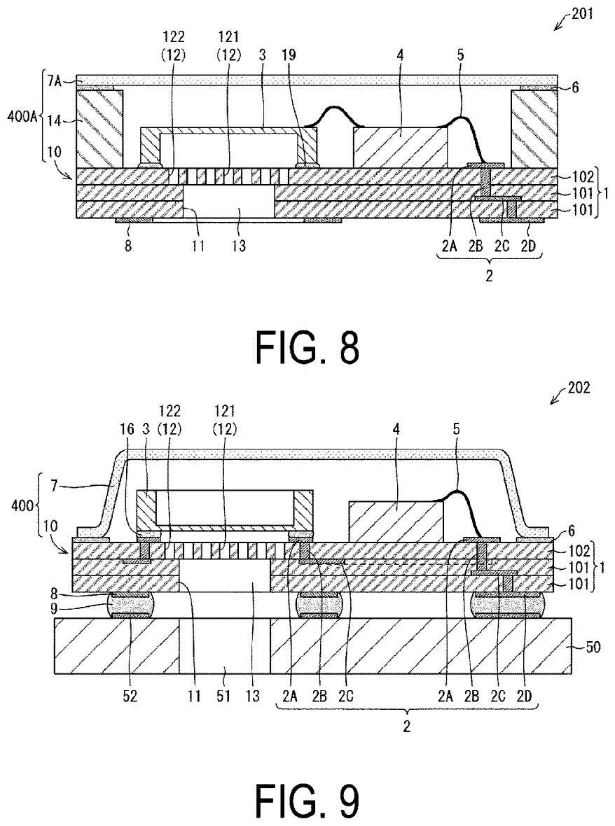

FIG. 8 is a cross-sectional view of a microphone device 201 which is a variation of the microphone device 200. The microphone device 201 includes a package 400A, the microphone element 3, and the semiconductor element 4. The package 400A includes the wiring board 10, a frame-shaped portion 14, and a lid 7A.

The frame-shaped portion 14 forms an accommodation recessed portion that houses the microphone element 3, a connection pad 2A, and the connecting member 5. The frame-shaped portion 14 may be made of the same insulation material as the ceramic substrate 1. The frame-shaped portion 14 may be integrally formed with the wiring board 10. The lid 7A has a flat plate shape and seals the opening of the accommodation recessed portion.

Other configurations of the microphone device 201 are the same as or similar to the configurations of the microphone device 200 of the first embodiment illustrated in FIG. 1. The frame-shaped portion 14 is integrally formed with the insulation layers (the first layer 101 and the second layer 102), and thus the wiring board 10 includes, on the upper surface, a cavity that houses the microphone element 3. As a result, by integrally forming the frame-shaped portion 14, the thickness of the wiring board 10 is increased, and thus the strength is improved. The bonding portion of the lid 7A is away from the mounting positions of the microphone element 3 and the semiconductor element 4, and thus influence of heat when the lid 7A is welded is reduced. The lid 7A has a flat plate shape, and thus manufacturing is easy and cost can be reduced.

In addition to the above configuration, a through-hole conductor may be provided penetrating through the frame-shaped portion 14 and connecting to the bonding metal layer 6, and the through-hole conductor may be connected to the ground potential via the wiring 2. With this configuration, it can function as a shield against the external electromagnetic waves together with the lid 7A made of a metal and bonded to the bonding metal layer 6. Thus, the microphone device 201 with less noise can be implemented.

### Second Variation of Microphone Device

FIG. 9 is a cross-sectional view of a microphone device 202 and a mounting substrate 50 as a variation. The microphone device 202 includes the package 400, the microphone element 3, and the semiconductor element 4. In the microphone device 202, the microphone element 3 and the wiring board 10 are flip-chip connected to each other. In other words, the microphone element 3 is connected to the connection pad 2A via a terminal 16. In this case, the microphone element 3 is connected to the semiconductor element 4 via the wiring 2 in the wiring board 10. FIG. 9 illustrates an example in which the microphone device 202 is provided with the lid 7 of a box type, but the configuration for protecting the microphone element 3, the semiconductor element 4, the connecting member 5, and the connection pad 2A is not limited to this example.

The microphone device 202 is mounted on the mounting substrate 50 such that the recessed portion 13 side of the wiring board 10 faces the mounting substrate 50. The microphone device 202 is mounted on the mounting substrate 50 by connecting the terminal electrode 2D and the sealing metal layer 8 of the microphone device 202 to a wiring 52 of the mounting substrate 50 via an electrically conductive bonding material 9. As a result, the microphone device 202 is electrically connected to the mounting substrate 50.

The sealing metal layer 8 is provided surrounding the opening of the recessed portion 13. The sealing metal layer 8 is bonded to the mounting substrate 50 via the electrically conductive bonding material 9 such as solder, and thus the likelihood of water entering through an opening portion 51 of the mounting substrate 50 and spreading through between the microphone device 202 and the mounting substrate 50 can be reduced. The electrically conductive bonding material 9 functions as a sealing material.

For example, when a resin adhesive (including a conductive adhesive) is used, as the electrically conductive bonding material 9, instead of solder, or when a non-adhesive sealing material such as an O-ring is inserted between the microphone device 202 and the mounting substrate 50, the sealing metal layer 8 may be unnecessary. The mounting method similarly applies to other embodiments.

### Third Variation of Microphone Device

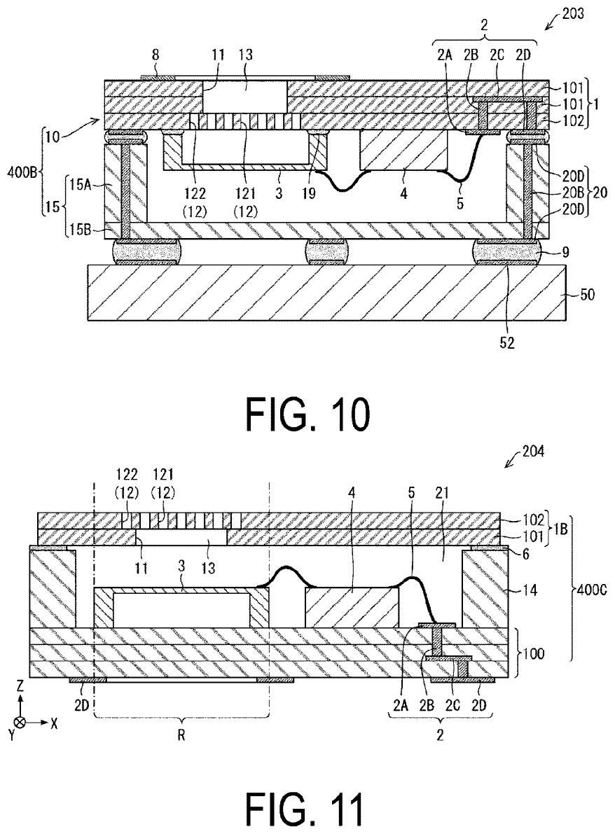

FIG. 10 is a cross-sectional view of a microphone device 203 and the mounting substrate 50, illustrating a variation of the embodiment in which the microphone device 203 is mounted with its lower surface (the lower surface of the wiring board 10) facing the side opposite to the side facing the mounting substrate 50. This mounting example is configured such that the microphone device 203 includes the first through-hole 11 (recessed portion 13) and the second through-holes 12 as the sound openings on the side opposite to the mounting substrate 50, and this mounting example is also referred to as an upper sound opening type.

The microphone device 203 includes a package 400B, the microphone element 3, and the semiconductor element 4. The package 400B includes the wiring board 10 and a relay substrate 15 (connecting substrate) for electrical connection with the mounting substrate 50. The wiring 2 of the wiring board 10 is drawn out to the upper surface of the wiring board 10. The relay substrate 15 includes a frame-shaped portion 15A and a flat plate portion 15B that blocks an opening of the frame-shaped portion 15A. The relay substrate 15 constitutes an insulator having a cap shape including a recessed portion with use of the frame-shaped portion 15A and the flat plate portion 15B. The relay substrate 15 includes wiring 20. The wiring 20 includes a terminal electrode 20D and a through-hole conductor 20B. The terminal electrode 20D connected to the connection pad 2A of the wiring board 10 is provided on the upper surface of the frame-shaped portion 15A. The terminal electrode 20D for connection to the external electrical circuit is provided on the lower surface of the flat plate portion 15B. These two terminal electrodes 20D are electrically connected by the through-hole conductor 20B provided inside the relay substrate 15. The through-hole conductor 20B is disposed penetrating through the frame-shaped portion 15A and the flat plate portion 15B. The wiring 20 electrically connects the wiring 2 of the wiring board 10 and the wiring 52 of the mounting substrate 50. The relay substrate 15 also serves as a lid, and seals the microphone element 3 and the like mounted on the wiring board 10.

In the example of FIG. 10, the electrically conductive bonding material 9 bonding the wiring board 10 and the relay substrate 15 functions as an electrical connection material and also functions as a sealing material. In the example of FIG. 10, the electrically conductive bonding material 9 may be provided by disposing an anisotropic conductive resin or the like in a frame shape along the outer periphery of the relay substrate 15. This enables sealing without a short circuit between the terminal electrodes 20D (between terminal electrodes 2D). the electrically conductive bonding material 9 may be used to connect the plurality of terminal electrodes 2D to the wiring 20 (terminal electrode 20D) of the relay substrate 15, outside of which the sealing material may be disposed. In a case where the sealing material is the brazing material, solder, or the like, a frame-shaped sealing metal layer for sealing material can be provided.

When the microphone device 203 is mounted in an electronic apparatus, the sealing metal layer 8 is bonded to the casing of the electronic apparatus via the electrically conductive bonding material 9 such as solder. Alternatively, the microphone device 203 may be bonded to the casing by a resin sealing material. When the resin sealing material is used, the first layer 101, which is located on the outermost side of the wiring board 10, may have through-holes, around the first through-hole, each having a diameter approximately equal to that of the second through-holes 12. This reduces the likelihood of spreading of the bonding material or the sealing material toward the first through-hole 11.

### Fourth Variation of Microphone Device

FIG. 11 is a cross-sectional view of a microphone device 204 as a variation. As illustrated in FIG. 11, the microphone device 204 includes a package 400C, the microphone element 3, and the semiconductor element 4. The package 400C includes the ceramic substrate 1B, the frame-shaped portion 14, and a wiring board 100. The wiring board 100 includes three insulation layers, and is provided with the wiring 2 through the inner portion of the wiring board 100 such that it is energized from the upper surface to the lower surface, but no such limitation is intended. The wiring board 100 only needs to include the element mounting region R where the wiring 2 and the microphone element 3 are mounted, and other structures are not particularly limited. As the wiring board 100, any known wiring board may be used.

The package 400C includes an accommodation recessed portion 21 (recessed portion) formed by the wiring board 100 and the frame-shaped portion 14 provided on the upper surface of the wiring board 100, and the accommodation recessed portion 21 can accommodate the members such as the microphone element 3, the semiconductor element 4, and the connecting member 5. The wiring board 100 may include the frame-shaped portion 14. That is, the wiring board 100 may include the accommodation recessed portion 21 and include the element mounting region R on the bottom surface of the accommodation recessed portion 21. The package 400C includes a ceramic substrate 1B disposed covering the accommodation recessed portion 21. The ceramic substrate 1B and the frame-shaped portion 14 may be bonded with the brazing material, for example, via the bonding metal layer 6 provided on the ceramic substrate 1B. A means for bonding the ceramic substrate 1B and the frame-shaped portion 14 is not particularly limited.

The ceramic substrate 1B differs from the ceramic substrate 1 described above in that the first layer 101 is composed of a single layer. That is, the ceramic substrate 1B includes one first layer 101 and one second layer 102. Other structures are the same as or similar to those of the ceramic substrate 1.

When the microphone device 204 is viewed in plane perspective, the ceramic substrate 1B has the first through-hole 11 (the recessed portion 13) at a position corresponding to the element mounting region R of the microphone element 3 in the package 400C.

The ceramic substrate 1B is waterproof to significantly reduce the likelihood of water entering the accommodation recessed portion, while having other performance requirements (for example, strength) for the lid. The ceramic substrate 1B is the lid in which the number of the effective through-holes has not been decreased due to the layering misalignment. When the microphone device 204 is mounted in the electronic apparatus, the microphone device 204 is bonded to the casing of the electronic apparatus, for example, with the resin sealing material. When the resin sealing material is provided surrounding the region where the second through-holes 12 are located, the presence of the outer through-holes 122 can reduce the likelihood of the sealing material spreading toward the effective through-holes, thus reducing the likelihood of a decrease in the number of the effective through-holes.

### Second Embodiment

Another embodiment of the present disclosure will be described below. For the sake of convenience of description, members having the same functions as those of the members described in the above-described embodiment are denoted by the same reference signs, and description thereof is not repeated. In a second embodiment, an example is described in which the ceramic substrate or the wiring board of the present disclosure is applied to a gas sensor device.

### Configuration of Gas Sensor Device 300

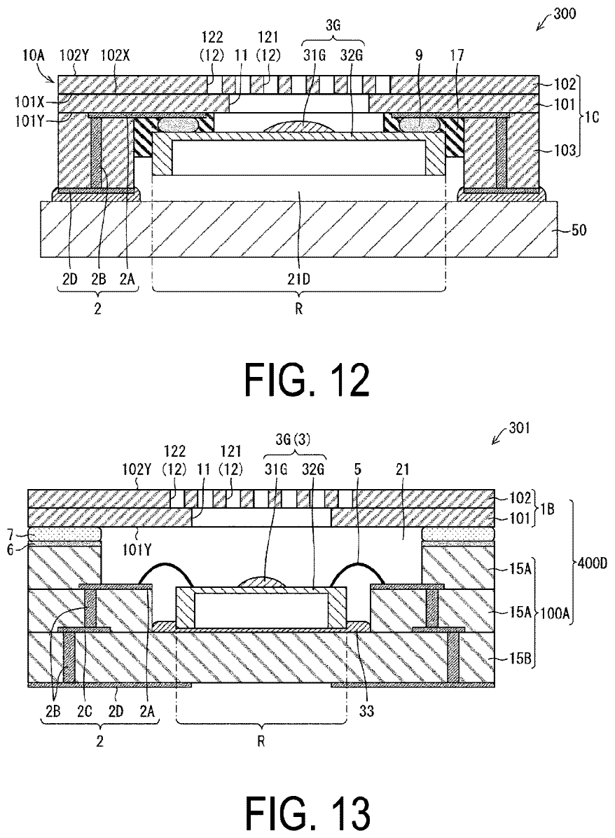

FIG. 12 is a cross-sectional view of a gas sensor device 300. FIG. 12 illustrates a cross section in a state in which the gas sensor device 300 is mounted on the mounting substrate 50. The gas sensor device 300 includes a wiring board 10A and a gas sensor element 3G.

The wiring board 10A includes a ceramic substrate 1C and the wiring 2. The ceramic substrate 1C includes the first layer 101 with the first through-hole 11, the second layer 102 with the second through-holes 12, and a frame portion 103. The frame portion 103 is located on the surface of the first layer 101 so as to surround the first through-hole 11.

As the gas sensor element 3G, for example, a substrate semiconductor-type gas sensor is used. The substrate semiconductor-type gas sensor is obtained by forming a thin film or a thick film of a semiconductor material serving as a gas sensing portion 31G on a surface of a support substrate 32G, and then firing the thin film or thick film. Comb-shaped platinum electrodes (not illustrated) are provided on the surface of the support substrate 32G, and a sensor output is obtained using a platinum wire wired between the electrodes as a signal wire. The gas sensing portion 31G is heated using a platinum heater (not illustrated) on the back side of the support substrate 32G. The gas sensor element 3G may be a MEMS-type semiconductor-based gas sensor using, as the support substrate, a MEMS substrate having a diaphragm structure and having a heater incorporated therein.

Generally, the gas sensing portion 31G detects gas in a state of being heated to a temperature of approximately 200° C. to 500° C. by the heater, but this varies depending on the types of gas detected. Therefore, the package containing the gas sensor element 3G is advisably made of a material that is unlikely to generate gas or corrode even when exposed to high temperatures. Ceramic is less susceptible to corrosion by various gases or moisture. Even when exposed to high temperatures, ceramic itself generates very little gas. In terms of the above, ceramic may be used as the material of the substrate of the gas sensor device 300.

The gas sensor element 3G is flip-chip connected to the ceramic substrate 1C. That is, the gas sensor element 3G is connected to the ceramic substrate 1C by bonding the electrodes (not illustrated) provided on the surface of support substrate 32G and the connection pad 2A with the electrically conductive bonding material 9 such as gold bumps and solder bumps, for example. Between the ceramic substrate 1C and the gas sensor element 3G, a sealing member 17 that decreases the volume of the space conducting to the outside is provided.

The sealing member 17 may be an underfill material for reinforcing the bonding strength of the gas sensor element 3G to the ceramic substrate 1C using the electrically conductive bonding material 9. The underfill material may be placed around the entire periphery of the gas sensor element 3G (support substrate 32G), not just around the electrically conductive bonding material 9 such as gold bumps or solder bumps. By filling the void between the gas sensor element 3G and the ceramic substrate 1C, the sealing member 17 can decrease the volume of the space conducting to the first through-hole 11.

In the example of FIG. 12, the gas sensor element 3G is flip-chip connected to the ceramic substrate 1C. This eliminates the need for height enough for accommodation of pads for the bonding wires and bonding loops, thus achieving a smaller and thinner gas sensor device 300.

The gas sensor device 300 includes the wiring board 10A and the gas sensor element 3G. This configuration allows implementation of the gas sensor device having ventilation and waterproof characteristics. The wiring board 10A is a substrate in which the number of effective through-holes has not been decreased due to the layering misalignment. Therefore, the gas sensor device 300 has excellent ventilation and sensitivity. When mounting the gas sensor device 300 on the electronic apparatus, the gas sensor device 300 may be mounted in the casing of the electronic apparatus such that the opening portion of the casing of the electronic apparatus is aligned with the position of the first through-hole 11. In this case, the sealing member or the like is provided along the outer edge of the region where the second through-holes 12 are formed.

When mounting the gas sensor device 300 on the electronic apparatus, the gas sensor device 300 is bonded to the casing of the electronic apparatus, for example, with the resin sealing material. When the resin sealing material is provided surrounding the region where the second through-holes 12 are located, the presence of the outer through-holes 122 can reduce the likelihood of the sealing material spreading toward the effective through-holes, thus reducing the likelihood of a decrease in the number of the effective through-holes. This reduces the likelihood of deterioration in sensitivity of the gas sensor device 300.

In the gas sensor device 300, the first layer 101 of the wiring board 10A has the third surface 101X facing the second layer 102 and the fourth surface 101Y located on the opposite side of the third surface. The fourth surface 101Y includes the element mounting region R, and the element mounting region R is located surrounding the first through-hole 11 in plan view.

With this configuration, in the wiring board 10A, elements can be mounted on the first layer 101 side where the first through-hole 11 is located. For example, when the wiring board 10A is used as a substrate for mounting the gas sensor element 3G, the gas sensor element 3G may be mounted on the fourth surface 101Y, whereby the gas sensing portion 31G can be accommodated inside the first through-hole 11. In the example of FIG. 12, the gas sensing portion 31G is located outside the first through-hole 11, but the gas sensing portion 31G may be accommodated in the first through-hole 11 by adjusting the thickness of the electrically conductive bonding material 9. This configuration enables a smaller gas sensor device 300. The gas sensing portion 31G can also be disposed at a position close to the outer surface of a package 400D. The air risen as a result of being heated in the gas sensing portion 31G is likely to accumulate in the second through-holes (recessed portions of the substrate), and thus discharge of the heated air is facilitated. Accordingly, more air outside the package can be taken in. This improves gas sensing sensitivity.

### Variation of Gas Sensor Device

FIG. 13 is a cross-sectional view of a gas sensor device 301 as a variation. The gas sensor device 301 includes a package 400D and the gas sensor element 3G. The package 400D includes the ceramic substrate 1B and a wiring board 100A that includes the wiring 2 and the accommodation recessed portion 21 accommodating the sensor element. The wiring board 100A includes the element mounting region R on the bottom surface of the accommodation recessed portion 21. The ceramic substrate 1B constitutes a lid of the package 400D. The gas sensor device 301 may have, for example, a quadrangle shape such as a rectangular shape or a square shape in plan view.

The ceramic substrate 1B is as described in the first embodiment. In the gas sensor device 301 illustrated in FIG. 13, the ceramic substrate 1B is disposed such that the first surface 102Y constitutes a part of the outer surface of the package 400D and the fourth surface 101Y faces the gas sensor element 3G.

The wiring board 100A is a substrate on which the gas sensor element 3G is mounted. The wiring board 100A has functions such as ensuring mechanical strength for a substrate for mounting the gas sensor element 3G and ensuring insulation between the plurality of wirings 2. The accommodation recessed portion 21 of the wiring board 100A can have any shape and any size as long as the size of the accommodation recessed portion 21 is large enough that it can accommodate the gas sensor element 3G. The shape of the inner side surface of the accommodation recessed portion 21 is not particularly limited either. As illustrated in FIG. 13, the inner side surface of the accommodation recessed portion 21 may have a stepped shape. The inner side surface may also be an inclined surface with respect to the bottom surface of the wiring board 100A. The wiring board 100A is provided with the wiring 2 inside and on the surface.

The above configuration allows implementation of the gas sensor device with ventilation and waterproof characteristics. Gas that has passed through the second through-holes 12 can easily further pass through the first through-hole 11 and proceed toward the gas sensing portion 31G of the gas sensor element 3G. Thus, sensor sensitivity can be improved.

The ceramic substrate 1B is waterproof to significantly reduce the likelihood of water entering the accommodation recessed portion, and has other performance requirements (for example, strength) for the lid. The ceramic substrate 1B is the lid in which the number of the effective through-holes has not been decreased due to the layering misalignment. When mounting the gas sensor device 301 on the electronic apparatus, the gas sensor device 301 is bonded to the casing of the electronic apparatus with, for example, the resin sealing material. When the resin sealing material is provided surrounding the region where the second through-holes 12 are located, the presence of the outer through-holes 122 can reduce the likelihood of the sealing material spreading toward the effective through-holes, thus reducing the likelihood of a decrease in the number of the effective through-holes. This reduces the likelihood of deterioration in sensitivity of the gas sensor device 301.

### Example of Mounting on Electronic Apparatus

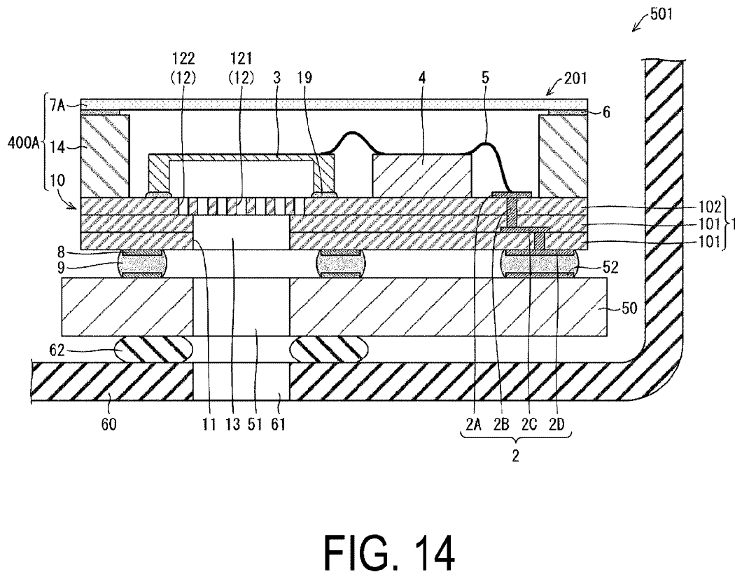

FIG. 14 is a partial cross-sectional view of an electronic apparatus 501 including the microphone device 201. Specific examples of the electronic apparatus in which the microphone device according to an aspect of the present disclosure is mounted include, but are not particularly limited to, communication information terminals such as smartphones, game machines, and earphones. The electronic apparatus 501 includes the microphone device 201, the mounting substrate 50, and a casing 60.

An opening portion 61 serving as the sound opening is formed in the casing 60 of the electronic apparatus 501. In the electronic apparatus 501, the microphone element 3, the opening portion 51 of the mounting substrate 50, and the opening portion 61 of the casing 60 are aligned and disposed so as to communicate with each other. A sealing material 62 having a ring shape is disposed between the casing 60 and the mounting substrate 50 along outer edges of the opening portion 61 and the opening portion 51. The sealing material 62 may be a solder material or a gasket. Examples of the material of the sealing material 62 include a rubber resin sealing material, and a metal such as solder. The sealing material 62 may be interposed between the casing 60 and the mounting substrate 50, or the casing 60 and the mounting substrate 50 may be attached (bonded) to each other by the sealing material 62.

The above configuration allows implementation of the electronic apparatus 501 having excellent waterproof and dustproof characteristics, while maintaining good acoustic characteristics because the number of the effective through-holes is not decreased.

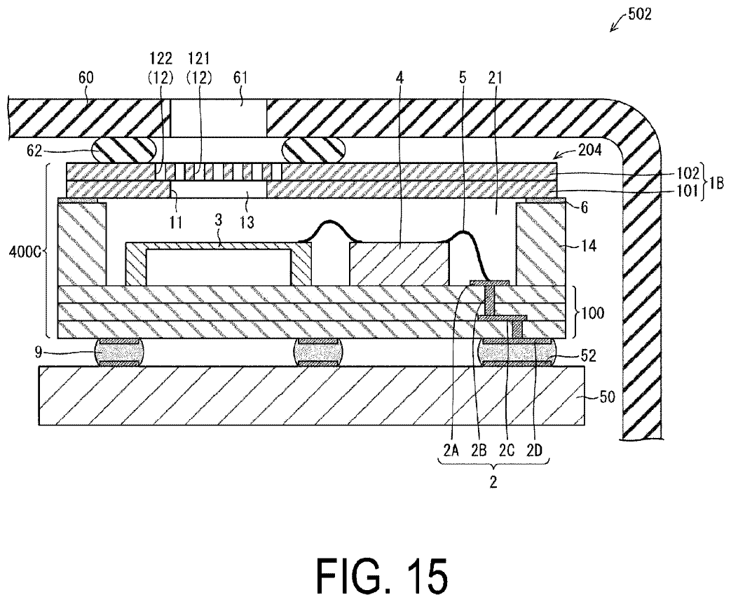

FIG. 15 is a partial cross-sectional view of an electronic apparatus 502 including the microphone device 204. The electronic apparatus 501 includes the microphone device 204, the mounting substrate 50, and the casing 60. In the electronic apparatus 502, the microphone element 3 and the opening portion 61 of the casing 60 are aligned and disposed so as to communicate with each other. The sealing material 62 may be disposed between the casing 60 and the mounting substrate 50 along the outer edge of the region where the opening portion 61 and the second through-holes 12 are located. Alternatively, the sealing material 62 may be disposed at a position overlapping a part of the outer through-holes 122 in plane perspective. When the sealing material 62 is a resin sealing material, the presence of the outer through-holes 122 can reduce the likelihood of spreading of the sealing material toward the effective through-holes, thus reducing the likelihood of a decrease in the number of the effective through-holes. This allows implementation of the electronic apparatus 501 having excellent waterproof and dustproof characteristics, while maintaining good acoustic characteristics because the effective through-holes are not decreased.

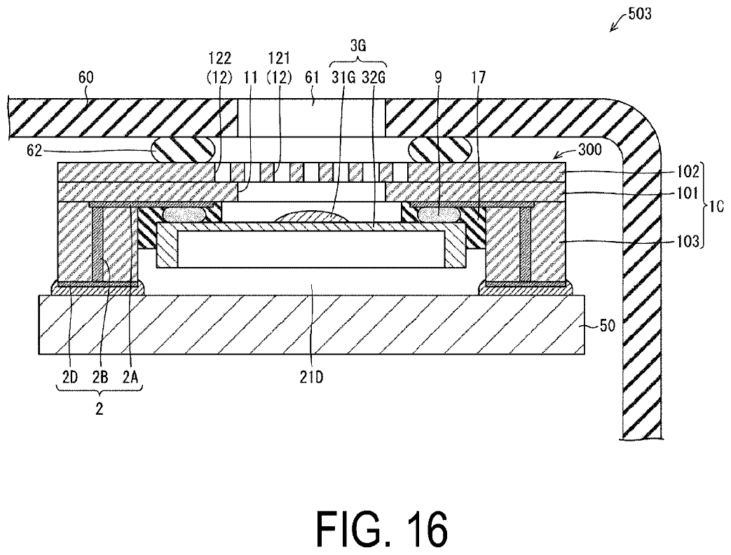

FIG. 16 is a cross-sectional view of an electronic apparatus 503 including the gas sensor device 300. Specific examples of the electronic apparatus in which the gas sensor device according to an aspect of the present disclosure is mounted include, but are not particularly limited to, a gas detector such as a gas leakage alarm, an alcohol checker, an air conditioner, and an air cleaner. The electronic apparatus 503 includes the gas sensor device 300, the mounting substrate 50, and the casing 60.

The electronic apparatus 503 is disposed such that the position of the first through-hole 11 is aligned with the position of the opening portion 61 in the casing 60. In other words, the electronic apparatus 503 is provided in which the gas sensor device 300 is mounted in the casing 60 so as to allow communication between the second through-holes 12, the first through-hole 11, and the opening portion 61. The sealing material 62 may be disposed between the gas sensor device 300 and the casing 60 along the outer edge of the region where the opening portion 61 and the second through-holes 12 are located. Alternatively, the sealing material 62 may be disposed at a position overlapping a part of the outer through-holes 122 in plane perspective. When the sealing material 62 is a resin sealing material, the presence of the outer through-holes 122 can reduce the likelihood of spreading of the sealing material toward the effective through-holes, thus reducing the likelihood of a decrease in the number of the effective through-holes. This allows implementation of the electronic apparatus 503 having excellent ventilation and high sensitivity, because the number of the effective through-holes is not decreased.

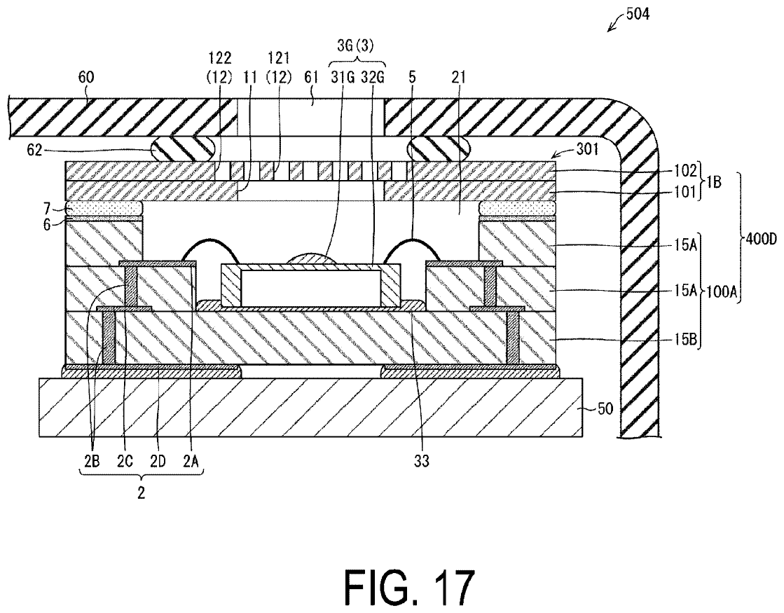

FIG. 17 is a cross-sectional view of an electronic apparatus 504 including a gas sensor device 301. The electronic apparatus 504 includes the gas sensor device 301, the mounting substrate 50, and the casing 60.

For this configuration, as with the electronic apparatus 503, when the sealing material 62 is a resin sealing material, the presence of the outer through-holes 122 can reduce the likelihood of spreading of the sealing material toward the effective through-holes, thus reducing the likelihood of a decrease in the number of the effective through-holes. This allows implementation of the electronic apparatus 504 having excellent ventilation and high sensitivity, because the number of the effective through-holes is not decreased.

In the present disclosure, the invention has been described above based on the various drawings and examples. However, the invention according to the present disclosure is not limited to each embodiment described above. That is, the embodiments of the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, a person skilled in the art can easily make various variations or modifications based on the present disclosure. Note that these variations or modifications are included within the scope of the present disclosure.

### REFERENCE SIGNS

1, 1A, 1B, 1C Ceramic substrate
2, 20, 22, 52 Wiring
3 Microphone element
3G Gas sensor element
10, 10A Wiring board
100, 100A Wiring board
11, 11A, 11B First through-hole
12 Second through-hole
121 Inner through-hole
122 Outer through-hole
21 Accommodation recessed portion (recessed portion)
200, 201, 202, 203, 204 Microphone device
300, 301 Gas sensor device
400, 400A, 400B, 400C, 400D Package
501, 502, 503, 504 Electronic apparatus

1. A ceramic substrate comprising:
at least one first layer provided with a first through-hole; and
at least one second layer located overlapping the first layer,
wherein the second layer is provided with a plurality of second through-holes each having a smaller hole diameter than the first through-hole, and
the second through-holes comprise a plurality of inner through-holes located in an inside region of the first through-hole in plan view and a plurality of outer through-holes located in an outside region of the first through-hole in plan view.

2. The ceramic substrate according to claim 1, wherein the second through-holes are in a staggered array in the second layer.

3. The ceramic substrate according to claim 1, wherein the outer through-holes are located in a region defined by a distance outward from an outer edge of the first through-hole by two hole pitches of the second through-holes in plan view.

4. A method for manufacturing a ceramic substrate, comprising:
forming a first through-hole in a first sheet being a ceramic green sheet;
forming a plurality of second through-holes each having a smaller hole diameter than the first through-hole in a region having an area larger than an opening area of the first through-hole in a second sheet being a ceramic green sheet; and
layering the first sheet and the second sheet in a manner that some of the plurality of second through-holes are located on an outer side of the first through-hole in plan view.

5. A wiring board comprising:
the ceramic substrate according to claim 1; and
a wiring.

6. The wiring board according to claim 5,
wherein the second layer comprises a second surface facing the first layer and a first surface located on an opposite side of the second surface,
the first surface comprises an element mounting region, and
the element mounting region is located surrounding the first through-hole in plan view.

7. The wiring board according to claim 5,
wherein the first layer comprises a third surface facing the second layer and a fourth surface located on an opposite side of the third surface,
the fourth surface comprises an element mounting region, and
the element mounting region is located surrounding the first through-hole in plan view.

8. A method for manufacturing a wiring board, comprising:
forming a first through-hole in a first sheet being a ceramic green sheet;
forming a plurality of second through-holes each having a smaller hole diameter than the first through-hole in a region having an area larger than an opening area of the first through-hole in a second sheet being a ceramic green sheet;
forming a wiring in the first sheet and/or the second sheet; and
layering the first sheet and the second sheet in a manner that some of the plurality of second through-holes are located on an outer side of the first through-hole in plan view.

9. A package comprising:
the ceramic substrate according to claim 1 as a lid; and
a wiring board comprising an element mounting region at a position overlapping the first through-hole in plan view.

10. The package according to claim 9,
wherein the wiring board is provided with a recessed portion, and
the element mounting region is provided on a bottom surface of the recessed portion.

11. A microphone device comprising:
the wiring board according to claim 5; and
a microphone element.

12. A gas sensor device comprising:
the wiring board according to claim 5, and
a gas sensor element.

13. A microphone device comprising:
the package according to claim 9; and
a microphone element.

14. A gas sensor device comprising:
the package according to claim 9; and
a gas sensor element.

15. An electronic apparatus comprising:
the microphone device according to claim 11.

16. An electronic apparatus comprising:
the gas sensor device according to claim 12.
